(19) United States
(12) Patent Application Publication
(10) Pub. No.: US 2011/0136347 A1
(43) Pub. Date: Jun. 9, 2011

(54) POINT-OF-USE SILYLAMINE GENERATION

(75) Inventors: Nicolay Y. Kovarsky, Sunnyvale, CA (US); Dmitry Lubomirsky, Cupertino, CA (US)

(73) Assignee: Applied Materials, Inc., Santa Clara, CA (US)

(21) Appl. No.: 12/901,979

(22) Filed: Oct. 11, 2010

Related U.S. Application Data
(60) Provisional application No. 61/253,719, filed on Oct. 21, 2009.

(51) Int. Cl. H01L 21/30; C23C 16/30; C23C 16/40; C23C 16/44

(52) U.S. Cl. 438/758; 427/248.1; 257/E21.211

(57) ABSTRACT

The production and delivery of a reaction precursor containing one or more silylamines near a point of use is described. Silylamines may include trisilylamine (TSA) but also disilylamine (DSA) and monosilylamine (MSA). Mixtures involving two or more silylamines can change composition (e.g. proportion of DSA to TSA) over time. Producing silylamines near a point-of-use limits changing composition, reduces handling of unstable gases and reduces cost of silylamine-consuming processes.

### CROSS-REFERENCES TO RELATED APPLICATIONS

This application claims the benefit of U.S. Prov. Pat. App. No. 61/253,719 filed Oct. 21, 2009, and titled “TSA AND DSA GENERATION AND PROPORTION CONTROL,” which is incorporated herein by reference for all purposes.

### BACKGROUND OF THE INVENTION

Silicon nitride and other silicon-and-nitrogen-containing films have been used as barrier layers and provide resistance to diffusion, oxidation, etch and chemical mechanical polishing. These films can also be used to form passivation layers above device layers. The high dielectric constant and density also provide benefits for applications involving gapfill as well as the formation of gate dielectric layers and optical waveguides.

Deposition of silicon nitride and silicon oxynitride may involve a variety of plasma-based chemical vapor deposition (CVD) techniques including plasma-enhanced CVD (PECVD) and high density plasma CVD (HDP-CVD). Most of these techniques involve exposing a substrate to separate silicon and nitrogen sources. Common silicon sources for plasma-based techniques include silane (SiH₄) and disilane (Si₂H₆) while common nitrogen sources include ammonia (NH₃) or even nitrogen (N₂). These films may also be produced without a plasma using, e.g., low-pressure CVD (LPCVD). Halogenated silanes are typically used instead of silane to improve the deposition rate when no plasma is present in the deposition system. Other deposition techniques may employ a plasma to excite a nitrogen or oxygen-containing precursor and combine the resulting plasma effluents with an unexcited silicon-containing precursor to form a flowable film.

Reactive precursors which supply both silicon and nitrogen are available which also enable film growth without direct plasma excitation of the precursor. These reactive precursors include trisilylamine (N(SiH₃)₃) and disilylamine (N(SiH₃)₂H), each of which may be expensive to procure and/or transport. There is a need to address the cost, availability and safety of reactive precursors containing both silicon and nitrogen. These and other needs are addressed in the present application.

### BRIEF SUMMARY OF THE INVENTION

The production and delivery of a reaction precursor containing one or more silylamines near a point of use is described. Silylamines may include trisilylamine (TSA) but also the less stable disilylamine (DSA) and monosilylamine (MSA). Mixtures involving two or more silylamines can change composition (e.g. proportion of DSA to TSA) over time. Producing silylamines near a point-of-use limits changing composition, reduces handling of unstable gases and reduces cost of silylamine-consuming processes.

Embodiments of the invention include methods of generating a silylamine-containing precursor near a point-of-use. The methods include synthesizing the silylamine-containing precursor proximal to a substrate processing region and reacting the silylamine-containing precursor to form a film on a substrate within the substrate processing region.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected operations for forming a film using point-of-use generated precursor according to disclosed embodiments.

FIG. 2 shows a substrate processing system according to embodiments of the invention.

FIG. 3A shows a substrate processing chamber according to embodiments of the invention.

FIG. 3B shows a showerhead of a substrate processing chamber according to embodiments of the invention.

### DETAILED DESCRIPTION OF THE INVENTION

The production and delivery of a reaction precursor containing one or more silylamines near a point of use is described. Silylamines may include trisilylamine (TSA) but also the disilylamine (DSA) and monosilylamine (MSA). Mixtures involving two or more silylamines can change composition (e.g. proportion of DSA to TSA) over time. Producing silylamines near a point-of-use limits changing composition, reduces handling of unstable gases and reduces cost of silylamine-consuming processes.

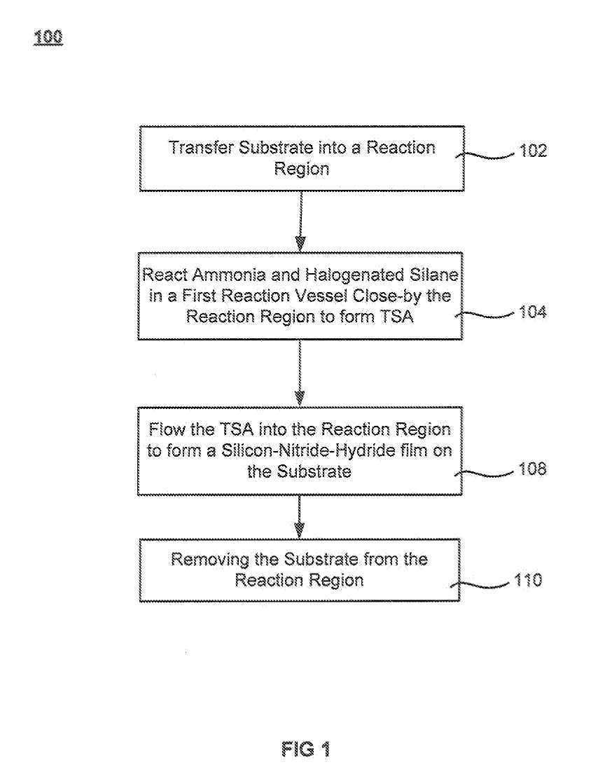

In order to better understand and appreciate the invention, reference is now made to FIG. 1 which is a flowchart illustrating selected operations (100) for forming a film using point-of-use generated precursor according to disclosed embodiments. A substrate is transferred into a reaction region (operation 102) and ammonia is reacted with monochlorosilane to produce a trisilylamine (TSA) precursor near the reaction region (operation 104). The reaction producing TSA takes place at or below room temperature in embodiments of the invention and produces ammonia chloride (NH₄Cl) by-product in the reaction cell. The TSA precursor may include some other components including disilylamine (DSA). A concentration of DSA, if present in the TSA precursor, typically will attenuate since DSA turns into TSA over time. The TSA precursor may be separated from the ammonia chloride by-product by filtration or centrifugation. The TSA precursor may be used shortly after its production or, alternatively, the TSA precursor may be stored for longer periods of time in a holding tank. Either way, the TSA precursor is flowed into the reaction region to form a silicon-nitride-hydride film on the substrate (operation 108). The substrate is then removed from the reaction region (operation 110).

The duration between generation and reaction of the TSA precursor is variable, therefore the order of operations 102 and 104 is selectable. Operation 102 precedes operation 104 in embodiments of the invention, while operation 104 precedes operation 102 in others.

The TSA precursor may be formed based on the reaction between a monochlorosilane and ammonia as shown in the following chemical reaction:

3SiH₃Cl+4NH₃→(SiH₃)₃N+3NH₄Cl(s)

This exemplary reaction may proceed in gas and/or liquid phases over a wide temperature range (from about −80° C. to about room temperature). A reaction cell is a compartment used to house the reaction which synthesizes the TSA precursor. A separate gas holding tank may be used to receive and hold the TSA precursor, in embodiments of the invention, after synthesis and before the TSA precursor is delivered to the substrate processing region. Alternatively, the holding tank and the reaction cell may be one and the same, in other words, the synthesis of the TSA precursor may occur in the same tank used to contain the TSA precursor after the separation from NH₃Cl/oligomers but prior to delivery into the substrate processing region. The TSA may also be separated from NH₃Cl/oligomers and then condensed into a liquid holding vessel to separate TSA from other gases (e.g. NH₃).

The yield of TSA may be increased to about 80% or more by ensuring reagents and reaction cell are pure and dry (essentially devoid of water content). The presence of water can decompose silane and silyl groups. The synthesis reaction forms solid ammonium chloride, TSA and some other products (e.g low-volatility oligomers [—SiH₂—NH—]ₙ as well as disilylamine (i.e. (SiH₃)₃NH or DSA). DSA is more unstable than TSA and converts to TSA in time by releasing NH₃:

3(SiH₃)₂NH→2(SiH₃)₃N+NH₃

Oligomers of the form (SiH₂NH)ₙ may also be produced by the decomposition of the DSA precursor, in embodiments. The production of oligomers during synthesis of TSA is typically undesirable since their production consumes a portion of the SiH₃Cl supply but produces silane gas (SiH₄) rather than a silylamine such as TSA or DSA:

n(SiH₃)₂NH→1/n[SiH₂NH]ₙ+nSiH₄

The undesirable production of oligomers during synthesis of TSA can be reduced (or even substantially eliminated) by ensuring a small excess (2-5%) of SiH₃Cl in the stoichiometric SiH₃Cl—NH₃ gas mixture. Performing TSA precursor synthesis at relatively low temperatures (e.g., between −60° C. and −20° C.) and/or pressures (1-100 Torr) may also reduce the formation of oligomers. Lastly, adding an inert gas in the reaction vessel (Ar, N₂, He, H₂) or using organic solvents (toluene, TGF etc) can also reduce oligomer formation, in embodiments of the invention. These techniques can be used alone or in combination with any number of the other techniques to further reduce the formation of oligomers.

For SiH₃Cl:4NH₃ volume ratios of about three to four (e.g. (3.05-3.1):4), a slight excess of SiH₃Cl is available for the reaction and essentially only one silicon containing product is produced, namely TSA. Reducing the volume ratio below three to four, the reaction proceeds with excess of ammonia and DSA, MSA, SiH₄ and Si—N—H oligomers are also produced in a small amount. NH₄Cl and oligomer particles may then be separated by filtering or other means to produce a gas mixture containing mainly TSA (e.g. >80%) and other gases (NH3, DSA,MSA). The TSA and other gases can be directly used by delivering into the substrate processing region. Altering the SiH₃Cl to NH₃ input ratio into the synthesis reaction cell allows the final gas composition to be selected (e.g. the DSA/MSA ratio may be selected). The amount of DSA and MSA in the synthesized product may be about a few % or less in embodiments of the invention. Even these small quantities are large enough to impact and therefore improve the control of the properties and flowability of Si—N—H CVD films.

It is also possible to increase amount of DSA in the gas product by adding a dihalogen-silane (preferably SiH₂Cl₂) to the reaction cell (containing SiH₃Cl and NH₃) or by using SiH₂Cl₂ instead of SiH₃Cl. The conditions required for the synthesis reaction of SiH₂Cl₂ and NH₃ in the reaction cell may be different from those for the SiH₃Cl and NH₃ reaction. The SiH₂Cl₂ and NH₃ reaction may benefit from the presence of a catalyst and/or a higher reaction temperature.

Following the formation of the gaseous TSA precursor, the gases may be separated from the solid NH₄Cl deposit by passing the combination through a suitable filter or processing the combination in a centrifuge. TSA may subsequently be extracted from the gaseous mixture by a low temperature condensation-distillation technique, in embodiments of the invention. The extraction process may take advantage of a difference in boiling points, melting points and/or vapor pressure of the gas components. TSA readily condenses at low temperatures (e.g. between −100° C. and −78° C.) under vacuum. The partial pressure of TSA near its melting point of −105° C. is low (around 0.01 Torr) and facilitates the separation of TSA from the other, more volatile, components. Other components (NH₃, SiH₄, SiH₃Cl) remain in the gas phase and are preferentially exhausted from the system. For example NH₃ has a melting point of −77° C. and a vapor pressure that exceeds the vapor pressure of TSA by a factor of about 300 at a processing temperature of about −100° C. It may be unnecessary to completely separate NH₃ from TSA, in embodiments of the invention, since NH₃ is combined with TSA in some CVD processes used to process substrates. In these CVD processes, a small content of NH₃ (1-5%) in TSA may be easily tolerated, especially when the TSA precursor is synthesized shortly before consumption.

The separation of TSA from other gases is easier in a closed system where partial pressure of TSA can be increased to between 2 and 20 Torr. Silane, ammonia and monochlorosilane are present in the gas phase between −60° C. and −30° C., allowing TSA to be condensed and separated. Gaseous SiH₃Cl and NH₃ convert into liquid TSA which occupies a very small volume compared with the initial volume of gases. This enables a large amount of liquid TSA product to be accumulated without significantly decreasing the volume available for additional synthesis by way of gas-phase reactions. The reduced effect on volume allows the progress of the reaction to be controlled by maintaining a relatively constant stoichiometry and pressure in the reactor.

As alluded to previously, Monochlorosilane is not the only precursor which can be combined with ammonia to produce the TSA precursor. More generally speaking, the TSA precursor may be formed based on the reaction between ammonia and a halogenated silane such as a monohalosilane (e.g. monochlorosilane SiH₃Cl, monobromosilane SiH₃Br or monoiodosilane SiH₃I) and ammonia NH₃. The halogenated silane is preferably SiH₃Cl. The halogenated silane may also be a di-halogenated silane such as di-chlorosilane SiH₂Cl₂, di-bromosilane SiH₂Br₂ and di-iodosilane SiH₂I₂ in embodiments of the invention. Di-halogenated silanes do not directly produce TSA but can replace or augment a flow of a monohalogenated silane(s) to increase the yield of DSA and/or MSA. The cost of the halogenated silane will help determine which precursor(s) to include in the synthesizing reaction to produce the TSA precursor. Costs may change and, therefore, so may the preferred halogenated silane to use in the synthesis of the TSA precursor. Process parameters may require adjustment when switching among halogenated silanes or to a new mixture of halogenated silanes. A wide range of process parameters, including pressure, temperature, type and concentration of reagents, reagent ratios, flows, catalysts etc) can be used to get TSA of desired amount and purity.

The synthesis reaction has been predominantly described as producing a TSA precursor. More generally speaking, the synthesis of the reaction precursor comprises at least one of TSA, disilylamine (SiH₃)₂NH (i.e., DSA) and monosilylamine (SiH₃)NH₂ (i.e., MSA) and will be referred to herein as a silylamine-containing precursor. The synthesis of silylamine-containing precursor occurs near the point of use and may occur within one meter or ten meters of the point of use. At least some of the synthesis occurs within these distances, in some embodiments, while the entire synthesis (i.e., conversion to silylamine-containing precursor) occurs within these distances in others.

Substrates processed according to the methods disclosed herein may have semiconducting material and may be silicon wafers, for example. The substrates may have relatively trenches which are filled by a flowable film formed using the synthesized silylamine-containing precursors formed near the point-of-use. The trenches may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths below 65 nm, 45 nm, 35 nm, 25 nm, 20 nm or 15 nm. Additional process parameters and operations will be introduced in the course of describing an exemplary substrate processing system which utilizes a silylamine precursor synthesized near the processing system (i.e. the point of use).

### Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

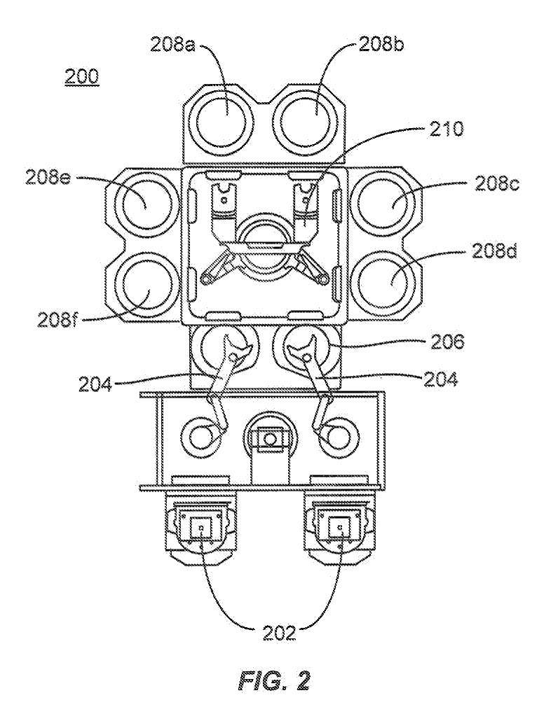

Embodiments of the deposition systems may be incorporated into larger fabrication systems for producing integrated circuit chips. FIG. 2 shows one such system 200 of deposition, baking and curing chambers according to disclosed embodiments. In the figure, a pair of FOUPs (front opening unified pods) 202 supply substrate substrates (e.g., 300 mm diameter wafers) that are received by robotic arms 204 and placed into a low pressure holding area 206 before being placed into one of the wafer processing chambers 208a-f. A second robotic arm 210 may be used to transport the substrate wafers from the holding area 206 to the processing chambers 208a-f and back.

The processing chambers 208a-f may include one or more system components for depositing, annealing, curing and/or etching a flowable dielectric film on the substrate wafer. In one configuration, two pairs of the processing chamber (e.g., 208c-d and 208e-f) may be used to deposit the flowable dielectric material on the substrate, and the third pair of processing chambers (e.g., 208a-b) may be used to anneal the deposited dielectic. In another configuration, the same two pairs of processing chambers (e.g., 208c-d and 208e-f) may be configured to both deposit and anneal a flowable dielectric film on the substrate, while the third pair of chambers (e.g., 208a-b) may be used for UV or E-beam curing of the deposited film. In still another configuration, all three pairs of chambers (e.g., 208a-f) may be configured to deposit and cure a flowable dielectric film on the substrate. In yet another configuration, two pairs of processing chambers (e.g., 208c-d and 208e-f) may be used for both deposition and UV or E-beam curing of the flowable dielectric, while a third pair of processing chambers (e.g. 208a-b) may be used for annealing the dielectric film. Any one or more of the processes described may be carried out on chamber(s) separated from the fabrication system shown in different embodiments.

In addition, one or more of the process chambers 208a-f may be configured as a wet treatment chamber. These process chambers include heating the flowable dielectric film in an atmosphere that include moisture. Thus, embodiments of system 200 may include wet treatment chambers 208a-b and anneal processing chambers 208c-d to perform both wet and dry anneals on the deposited dielectric film.

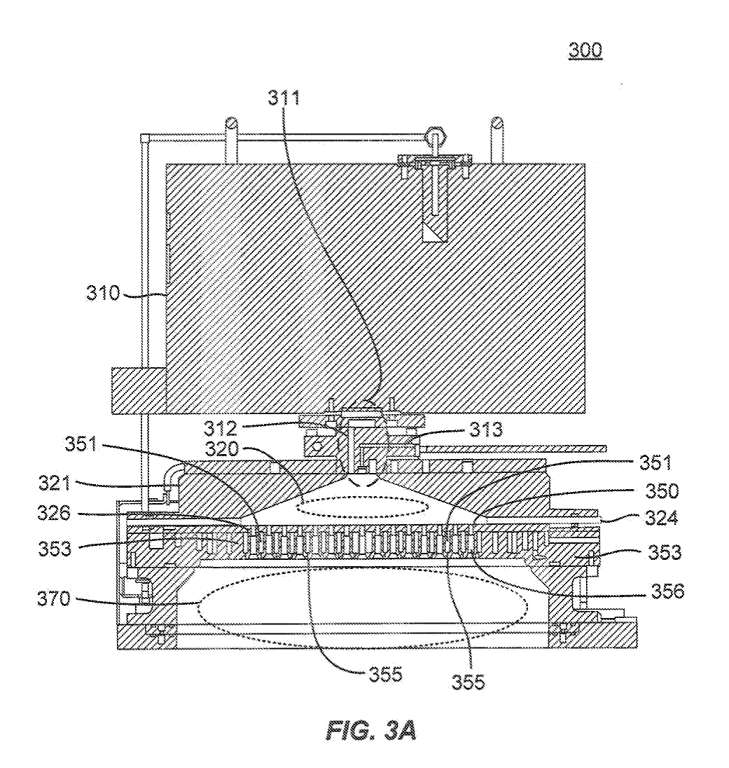

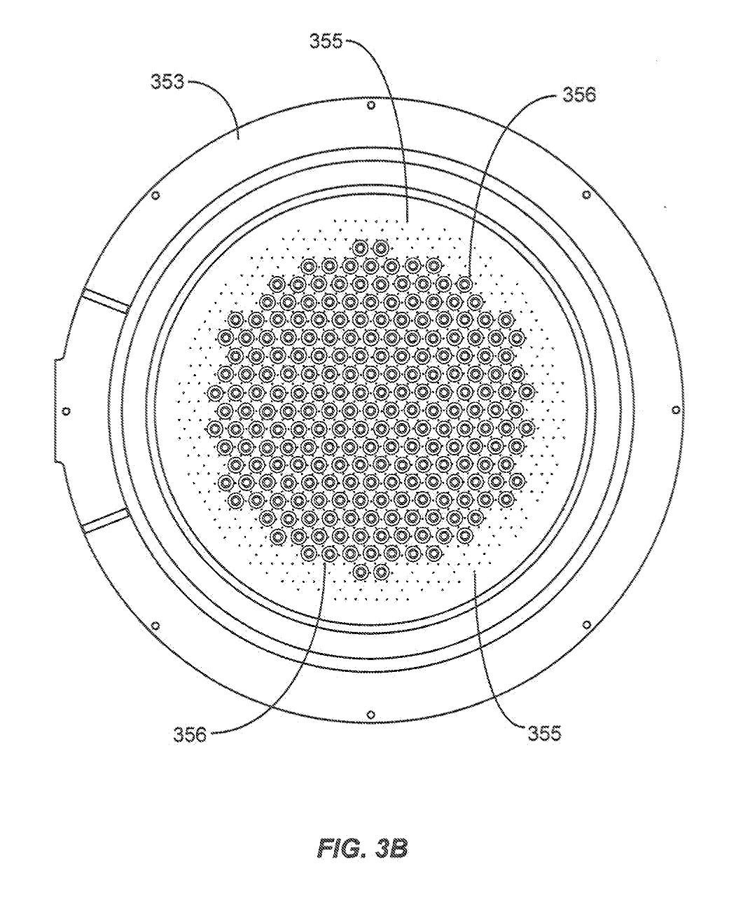

FIG. 3A is a substrate processing chamber 300 according to disclosed embodiments. A remote plasma system (RPS) 310 may process a gas which then travels through a gas inlet assembly 311. Two distinct gas supply channels are visible within the gas inlet assembly 311. A first channel 312 carries a gas that passes through the remote plasma system RPS 310, while a second channel 313 bypasses the RPS 300. The first channel 302 may be used for the process gas and the second channel 313 may be used for a treatment gas in disclosed embodiments. The lid (or conductive top portion) 321 and a perforated partition 353 are shown with an insulating ring 324 in between, which allows an AC potential to be applied to the lid 321 relative to perforated partition 353. The process gas travels through first channel 312 into chamber plasma region 320 and may be excited in a plasma in chamber plasma region 320 alone or in combination with RPS 310. Either region alone or the combination of chamber plasma region 320 and RPS 310 may be referred to as a remote plasma system herein. The perforated partition (also referred to as a showerhead) 353 separates chamber plasma region 320 from a substrate processing region 370 beneath showerhead 353. Showerhead 353 allows a plasma present in chamber plasma region 320 to avoid directly exciting gases in substrate processing region 370, while still allowing excited species to travel from chamber plasma region 320 into substrate processing region 370.

Showerhead 353 is positioned between chamber plasma region 320 and substrate processing region 370 and allows plasma effluents (excited derivatives of precursors or other gases) created within chamber plasma region 320 to pass through a plurality of through holes 356 that traverse the thickness of the plate. The showerhead 353 also has one or more hollow volumes 351 which can be filled with a precursor in the form of a vapor or gas (such as a silylamine-containing precursor) and pass through small holes 355 into substrate processing region 370 but not directly into chamber plasma region 320. Showerhead 353 is thicker than the length of the smallest diameter 350 of the through-holes 356 in this disclosed embodiment. In order to maintain a significant concentration of excited species penetrating from chamber plasma region 320 to substrate processing region 370, the length 326 of the smallest diameter 350 of the through-holes may be restricted by forming larger diameter portions of through-holes 356 part way through the showerhead 353. The length of the smallest diameter 350 of the through-holes 356 may be the same order of magnitude as the smallest diameter of the through-holes 356 or less in disclosed embodiments.

In the embodiment shown, showerhead 353 may distribute (via through holes 356) process gases which contain oxygen, hydrogen and/or nitrogen and/or plasma effluents of such process gases upon excitation by a plasma in chamber plasma region 320. In embodiments, process gases excited in RPS 310 and/or chamber plasma region 320 include ammonia (NH₃) and nitrogen (N₂) and/or hydrogen (H₂). Generally speaking, the process gas introduced into the RPS 310 and/or chamber plasma region 320 through first channel 312 may contain one or more of oxygen (O₂), ozone (O₃), N₂O, NO, NO₂, NH₃, NₓH_{y} including N₂H₄, silane, disilane, TSA and DSA. The process gas may also include a carrier gas such as helium, argon, nitrogen (N₂), etc. The second channel 313 may also deliver a process gas and/or a carrier gas, and/or a film-curing gas used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 356 may be between about 60 and about 2000. Through-holes 356 may have a variety of shapes but are most easily made round. The smallest diameter 350 of through holes 356 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 355 used to introduce a gas into substrate processing region 370 may be between about 100 and about 5000 or between about 500 and about 2000 in different embodiments. The diameter of the small holes 355 may be between about 0.1 mm and about 2 mm.

FIG. 3B is a bottom view of a showerhead 353 for use with a processing chamber according to disclosed embodiments. Showerhead 353 corresponds with the showerhead shown in FIG. 3A. Through-holes 356 are depicted with a larger inner-diameter (ID) on the bottom of showerhead 353 and a smaller ID at the top. Small holes 355 are distributed substantially evenly over the surface of the showerhead, even amongst the through-holes 356 which helps to provide more even mixing than other embodiments described herein.

An exemplary film is created on a substrate supported by a pedestal (not shown) within substrate processing region 370 when plasma effluents arriving through through-holes 356 in showerhead 353 combine with a silylamine-containing precursor arriving through the small holes 355 originating from hollow volumes 351. Though substrate processing region 370 may be equipped to support a plasma for other processes such as curing, no plasma is present during the growth of the exemplary film.

In embodiments employing a chamber plasma region, the radical-nitrogen precursor is generated in a section of the substrate processing system partitioned from a substrate processing region where the precursors mix and react to deposit the silicon-and-nitrogen layer on a deposition substrate (e.g., a semiconductor wafer). The radical-nitrogen precursor may also be accompanied by a carrier gas such as helium, argon etc. The substrate processing region may be described herein as “plasma-free” during the growth of the silicon-and-nitrogen-containing layer and during the low temperature ozone cure. “Plasma-free” does not necessarily mean the region is devoid of plasma. Ionized species created within the plasma region do travel through pores (apertures) in the partition (showerhead) but the silylamine-containing precursor is not substantially excited by the plasma power applied to the plasma region in embodiments of the invention. The borders of the plasma in the chamber plasma region are hard to define and may encroach upon the substrate processing region through the apertures in the showerhead. In the case of an inductively-coupled plasma (ICP), a small amount of ionization may be effected within the substrate processing region directly. Furthermore, a low intensity plasma may be created in the substrate processing region without eliminating the flowable nature of the forming film. Plasmas in the substrate processing region having much lower ion density than the chamber plasma region during the creation of the radical nitrogen precursor do not deviate from the scope of “plasma-free” as used herein.

In the substrate processing region, the silylamine-containing precursor and the radical-nitrogen precursor mix and react to form a silicon-and-nitrogen-containing film on the deposition substrate (operation 108). The deposited silicon-and-nitrogen-containing film may deposit conformally with recipe combinations which result in low deposition rates or high radical nitrogen fluxes at the deposition surface. In other embodiments, the deposited silicon-and-nitrogen-containing film has flowable characteristics unlike conventional silicon nitride (Si₃N₄) film deposition techniques. The flowable nature of the formation allows the film to flow into narrow gaps trenches and other structures on the deposition surface of the substrate. The temperature of the substrate during deposition (operation 108) is less than 120° C., less than 100° C., less than 80° C. and less than 60° C. in different embodiments.

The flowability may be due to a variety of properties which result from mixing a radical-nitrogen precursors with the unexcited silylamine-containing precursor. These liquid-like properties may include a significant hydrogen component in the deposited film and/or the presence of short chained linear and/or branched polysilazane polymers. A higher ratio of linear to branched chains lowers the initial viscosity of a polysilazane film and slows the solidification of the film. TSA tends to form branched chains while DSA tends to form linear chains. These short chains grow and network, so the liquid-like film converts into more dense dielectric material during and after the formation of the film. For example the deposited film may have a silazane-type, Si—NH—Si backbone (i.e., a Si—N—H film). When both the silicon-containing precursor and the radical-nitrogen precursor are carbon-free, the deposited silicon-and-nitrogen-containing film is also substantially carbon-free. Lack of carbon decreases shrinkage during subsequent processing steps, such as curing and annealing. Of course, “carbon-free” does not necessarily mean the film lacks even trace amounts of carbon. Carbon contaminants may be present in the precursor materials that find their way into the deposited silicon-and-nitrogen precursor. The amount of these carbon impurities however are much less than would be found in a silicon-containing precursor having a carbon moiety (e.g., TEOS, TMDSO, etc.).

Methods described herein may include forming a flowable film on a substrate comprising a gap. The substrate may have a plurality of gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., about 90 nm or less, 65 nm or less, 45 nm or less, 32 nm or less, 28 nm or less, 22 nm or less, 16 nm or less, etc.).

A plasma may be ignited either in chamber plasma region 320 above showerhead 353 or substrate processing region 370 below showerhead 353. A plasma is present in chamber plasma region 320 to produce the radical nitrogen precursor from an inflow of a nitrogen-and-hydrogen-containing gas. An AC voltage typically in the radio frequency (RF) range is applied between the conductive top portion 321 of the processing chamber and showerhead 353 to ignite a plasma in chamber plasma region 320 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 370 is turned on to either cure a film or clean the interior surfaces bordering substrate processing region 370. A plasma in substrate processing region 370 is ignited by applying an AC voltage between showerhead 353 and the pedestal or bottom of the chamber. A cleaning gas may be introduced into substrate processing region 370 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the CVD machine. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack on a substrate or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” may include minority concentrations of other elemental constituents such as nitrogen, hydrogen, carbon and the like. A gas in an “excited state” describes a gas wherein at least some of the gas molecules are in vibrationally-excited, dissociated and/or ionized states. A gas may be a combination of two or more gases. The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. The term “precursor” is used to refer to any process gas which takes part in a reaction to either remove or deposit material from a surface.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of generating a silylamine-containing precursor near a point-of-use, the method comprising:
synthesizing the silylamine-containing precursor proximal to a substrate processing region; and
reacting the silylamine-containing precursor to form a film on a substrate within the substrate processing region.

2. The method of claim 1 wherein the substrate comprises a semiconducting material.

3. The method of claim 1 wherein the substrate comprises a trench which is substantially filled by the film.

4. The method of claim 1 wherein the silylamine-containing precursor comprises TSA.

5. The method of claim 1 wherein the silylamine-containing precursor comprises at least one of the group of precursors consisting of TSA, DSA and MSA.

6. The method of claim 1 wherein the silylamine-containing precursor comprises both TSA and DSA.

7. The method of claim 1 wherein the silylamine-containing precursor is synthesized within ten meters of the substrate processing region.

8. The method of claim 1 wherein the silylamine-containing precursor is synthesized within one meter of the substrate processing region.

9. The method of claim 1 wherein the operation of synthesizing the silylamine-containing precursor comprises reacting ammonia with a halogenated silane to form the silylamine in the silylamine-containing precursor.

10. The method of claim 1 wherein the film is a silicon-and-nitrogen-containing layer.

11. The method of claim 1 wherein the film is flowable shortly after deposition.

12. The method of claim 10 wherein the silicon-and-nitrogen-containing layer is subsequently converted to silicon oxide.

13. The method of claim 9 wherein the halogenated silane is monochlorosilane.

14. The method of claim 9 wherein the halogenated silane is a mono-halogenated silane selected from SiH₃Cl, SiH₃Br and SiH₃I.

15. The method of claim 9 wherein the halogenated silane is a di-halogenated silane selected from SiH₂Cl₂, SiH₂Br₂ and SiH₂I₂.

16. The method of claim 9 wherein the halogenated silane is a halogenated polysilane comprising more than one silicon atom.
